(19) United States
(12) Patent Application Publication
(10) Pub. No.: US 2008/0048727 A1
(43) Pub. Date: Feb. 28, 2008

(54) Sense amplifier-based latch

(75) Inventors: Der-Min Yuan, Hsin Chuang City (TW); Shih-Hsing Wang, Hsinchu City (TW)

Correspondence Address: BIRCH STEWART KOLASCH & BIRCH, PO BOX 747, FALLS CHURCH, VA, 22040-0747, US

(73) Assignee: Etron Technology, Inc.

(21) Appl. No.: 11/808,865

(22) Filed: Jun. 13, 2007

(30) Foreign Application Priority Data
Aug. 25, 2006 (TW) 095131247

(51) Int. Cl. G11C 7/00

(52) U.S. Cl. 327/51

(57) ABSTRACT

A sense amplifier-based latch is provided. It comprises an input circuit, a sense amplifier, a latch circuit and an output circuit. By employing the latch circuit, the variation frequency of an output signal and a complementary output signal as well as lots of charge consumption is reduced. Accordingly, the invention has less glitches and malfunctions, thus suitable for high-speed circuit applications.

### BACKGROUND OF THE INVENTION

1. Field of the invention

The invention relates to a latch, and, more particularly, to a sense amplifier-based latch.

2. Description of the Related Art

FIG. 1 shows a simplified data-path schematic diagram from a memory cell to a data line sense amplifier according to a conventional dynamic random access memory (DRAM) architecture. Referring to FIG. 1, after a transistor 112 is switched on by asserting a word line WL, binary data stored as a charge in a capacitor C is retrieved all the way from a memory cell 110, a bit line BL, a bit switch 122 responsive to a control signal BSEN, a local data line LDQ, a main data switch (or transmission gate) 124 responsive to a control signal SWEN, a master data line (MDQ) to an I/O data bus. While finally arriving at the I/O data bus, the amplitude of binary data is relatively low. Therefore, in the conventional DRAM architecture, there are two sense amplifiers installed for amplifying signals as follows: a bit line sense amplifier (BLSA) 120 and a master data line sense amplifier (MDQSA) 130. The latter is shared among N pairs of master data lines (MDQ1/MDQ1B˜MDQN/MDQNB) and is the subject of this specification.

FIG. 2 is a timing diagram of operations of a conventional MDQSA. Referring to FIG. 2, while a data isolation signal SAISO is enabled (at a low voltage level), there is one single pair of MDQ, e.g., a master data line signal MDQ and its complement MDQB, among N pairs of MDQ being allowed to enter a MDQSA (not shown). Afterward, two complemented signals MDQ, MDQB are amplified to generate an output signal DT and a complementary output signal DTB after a control signal SAEN is enabled (at a high voltage level). According to the timing diagram of FIG. 2, two complemented signals DT, DTB generally remain at a low voltage level except that their respective data are outputted during an interval data_window. Since two complemented signals DT, DTB get toggled repeatedly, power consumption is relatively high and more glitches are created, thus easy to cause malfunctions. On the other hand, if a control circuit attempts to correctly fetch data contained in two complemented signals DT, DTB, the circuit complexity is relatively high due to a short interval data_window.

### SUMMARY OF THE INVENTION

In view of the above-mentioned problems, an object of the invention is to provide a sense amplifier-based latch, not only reducing power consumption, but also suitable for high speed memory applications.

To achieve the above-mentioned object, the sense amplifier-based latch comprises a sense amplifier and a latch circuit. The sense amplifier, responsive to a first control signal and a second control signal, amplifies both an input signal and a complementary input signal to generate an amplified signal and a complementary amplified signal. The latch circuit latches voltage levels of both the amplified signal and the complementary amplified signal and generates an output signal and a complementary output signal.

According to an embodiment of the invention, the sense amplifier-based latch further comprises an input circuit and an output circuit. The input circuit comprises a plurality of identical input units, each of which responsive to a data isolation signal receives a master data line signal and a complementary master data line signal. There is one single data isolation signal corresponding to one of the plurality of input units is enabled in each period of time such that both the master data line signal and the complementary master data line signal received by the enabled input unit are then outputted as the input signal and the complementary input signal. The output circuit, responsive to a third control signal, receives both the output signal and the complementary output signal and sends the voltage level of the output signal to an I/O data bus.

Wherein, the latch circuit can be implemented with either two NAND gates or two NOR gates.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1 shows a simplified data-path schematic diagram from a memory cell to a data line sense amplifier according to a conventional dynamic random access memory (DRAM) architecture.

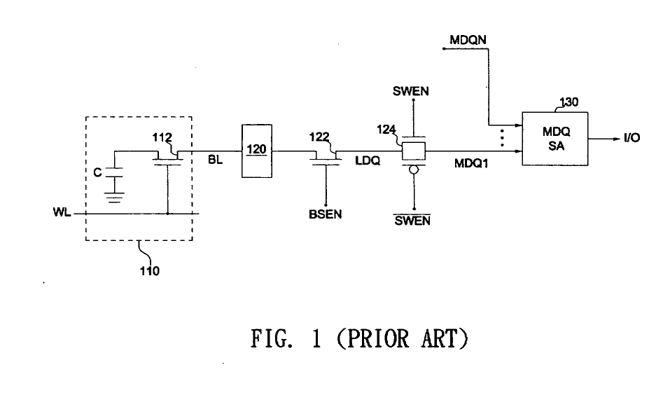

FIG. 2 is a timing diagram of operations of a conventional MDQSA.

FIG. 3 is a schematic diagram according to an embodiment of the invention.

FIG. 4 is a timing diagram according to the invention.

FIG. 5 is a detailed diagram of the sense amplifier shown in FIG. 3.

### DETAILED DESCRIPTION OF THE INVENTION

The sense amplifier-based latch of the invention will be described with reference to the accompanying drawings.

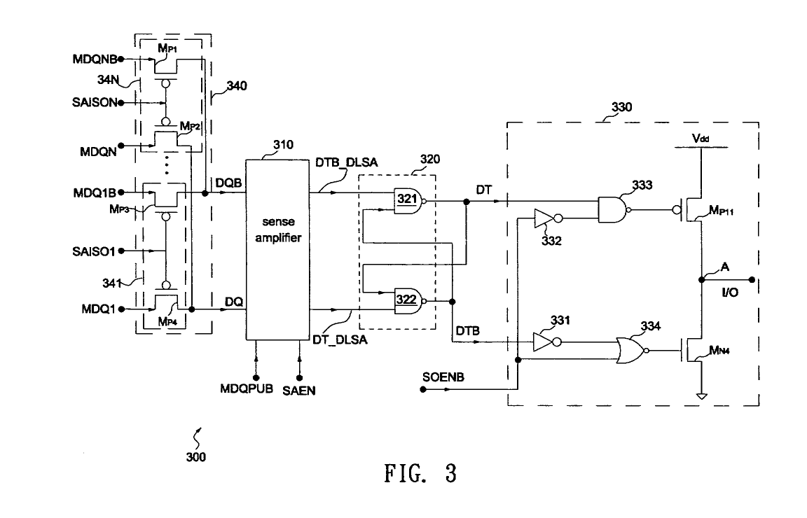

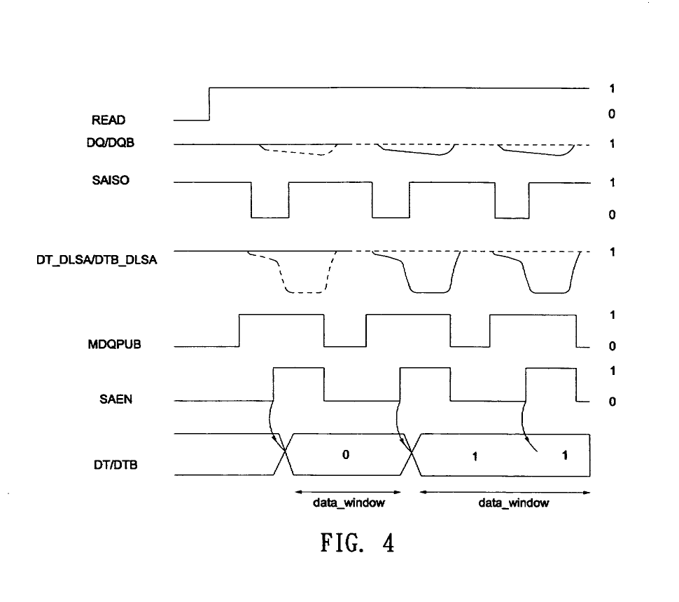

FIG. 3 is a schematic diagram according to an embodiment of the invention. FIG. 4 is a timing diagram according to the invention.

Referring to FIG. 3, according to an embodiment of the invention, a sense amplifier-based latch 300, applicable to ordinary DRAM circuits, comprises an input circuit 340, a sense amplifier 310, a latch circuit 320 and an output circuit 330. The input circuit 340 comprises a plurality of identical input units 341˜34N (N≧1, N is a positive integer), each of which receives both a master data line signal (MDQ1˜MDQN) and a complementary master data line signal (MDQ1B˜MDQNB) in response to a data isolation signal (SAISO1˜SAISON). Meanwhile, there is one single data isolation signal corresponding to one of the input units 341˜34N is enabled (SAISO is at a low voltage level as shown in FIG. 4) in each period of time such that the master data line signal and the complementary master data line signal previously received by the enabled input unit are then outputted as the input signal DQ and the complementary input signal DQB (not shown).

The latch circuit 320 is used to latch voltage levels of an amplified signal DT_DLSA and a complementary amplified signal DTB_DLSA and then generate an output signal DT and a complementary output signal DTB. In this embodiment, the latch circuit 320, which is implemented with two NAND gates 321, 322, is a typical S-R latch. Alternatively, the latch circuit 320 can be implemented with two NOR gates as well. However, the latch circuit is not limited to either two NAND gates or two NOR gates but includes other configurations, as the latch circuit may be modified and practiced in different but equivalent manners apparent to those skilled in the art having the benefit of the teachings herein.

The output circuit 330 comprises two NOT gates 331, 332, a NAND gate 333, a NOR gate 334, a PMOS transistor Mₚ₁₁ and a NMOS transistor M_{N4}. The output circuit 330 is responsive to a control signal SOENB. While being at a low voltage level, the control signal SOENB is inverted to a high voltage level right away. That allows both the output signal DT (i.e., the amplified input signal DQ) to pass through the NAND gate 333 and the complementary output signal DTB (i.e., the complementary amplified input signal DQB) to pass through the NOT gate 331 and the NOR gate 334. Then, the voltage level of the output signal DT is able to be correctly delivered to an I/O data bus via a node A after the PMOS transistor Mₚ₁₁ and the NMOS transistor M_{N4} are switched on.

In response to two control signals MDQPUB, SAEN, the sense amplifier 310 amplifies the input signal DQ and the complementary input signal DQB and then generates the amplified signal DT_DLSA and the complementary amplified signal DTB_DLSA. Hereinafter, the operations of the sense amplifier 310 will be detailed as follows.

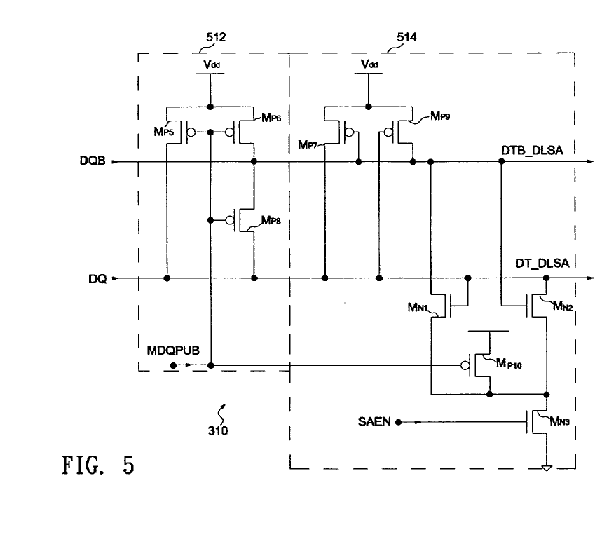

FIG. 5 is a detailed diagram of the sense amplifier shown in FIG. 3.

The sense amplifier 310 comprises a pre-charge circuit 512 and an amplifier circuit 514. In response to the control signal MDQPUB, the pre-charge circuit 512, comprising three PMOS transistors Mₚ₅, Mₚ₆, Mₚ₈, is used to pre-charge voltage levels of the amplified signal DT_DLSA and the complementary amplified signal DTB_DLSA to a pre-defined voltage level (such as V_{dd}) before receiving the input signal DQ and the complementary input signal DQB. With respect to the circuit architecture, sources of transistors Mₚ₅, Mₚ₆ are connected to an operating voltage V_{dd} while the drain of a transistor Mₚ₆ and the source of a transistor Mₚ₈ are connected to receive the complementary input signal DQB. Drains of transistors Mₚ₅, Mₚ₈ receive the input signal DQ while gates of three PMOS transistors Mₚ₅, Mₚ₆, Mₚ₈ are connected to each other in response to the control signal MDQPUB. Referring back to FIG. 4, while the control signal MDQPUB is at a low voltage level, three PMOS transistors Mₚ₅, Mₚ₆, Mₚ₈ are simultaneously switched on, thereby pre-charging both the amplified signal DT_DLSA and the complementary amplified signal DTB_DLSA to a pre-defined voltage level V_{dd}. It should be noted that there is no charge consumption in other circuits while the pre-charge circuit 512 is pre-charging.

On the other hand, the amplifier circuit 514 is simultaneously responsive to two control signals MDQPUB, SAEN. As shown in FIG. 4, while control signals MDQPUB, SAEN are at a high voltage level, the amplifier circuit 514 is used to amplify voltage levels of the input signal DQ and the complementary input signal DQB and then generate the amplified signal DT_DLSA and the complementary amplified signal DTB_DLSA. According to the embodiment, the amplifier circuit 514 is a cross-coupled sense amplifier, comprising three PMOS transistors Mₚ₇, Mₚ₉, Mₚ₁₀ and three NMOS transistors M_{N1}, M_{N2}, M_{N3}. With respect to the circuit architecture, sources of transistors Mₚ₇, Mₚ₉ are connected to the operating voltage V_{dd} while the source of the transistor M_{N3} is grounded. Drains of transistors Mₚ₁₀, M_{N3} and sources of transistors M_{N1}, M_{N2} are connected to each other. Drains of transistors Mₚ₉, M_{N1} and gates of transistors M_{N1}, M_{N2} are connected to receive the complementary input signal DQB while drains of transistors Mₚ₇, M_{N2} and gates of transistors Mₚ₉, M_{N1} are connected to receive the input signal DQ. The transistors Mₚ₁₀, M_{N3} are responsive to the control signals MDQPUB, SAEN, respectively. As shown in FIG. 4, while the control signals MDQPUB, SAEN are at a high voltage level, an imperceptible voltage difference between two complemented signals DQ, DQB is amplified by the amplifier circuit 514 such that the resultant voltage difference between the amplified signal DT_DLSA and the complementary amplified signal DTB_DLSA is enlarged.

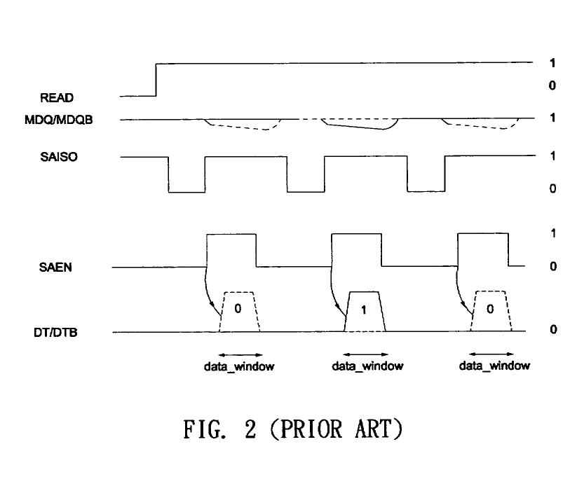

Comparing two respective waveforms of two complemented signals DT/DTB shown in FIG. 2 and FIG. 4, it is obvious that the variation frequency of two complemented signals DT/DTB shown in FIG. 4 is lower than that of two complemented signals DT/DTB shown in FIG. 2. The voltage levels of two complemented signals DT/DTB shown in FIG. 4 remain fixed except that the data contained in two complemented signals DT/DTB change. This is one advantage of the invention which results from employing the latch circuit 320. Referring to FIG. 4, there is no voltage variation in the waveforms of two complemented signals DT/DTB while the next data contained in the output signal DT is equal to the previous data (e.g., equal to 1) contained in the output signal DT The sense amplifier 310 has no additional charge consumption except to perform the sense and the pre-charge operations. Therefore, the invention reduces a lot of charge consumption as well as glitches and malfunctions for memory circuits.

On the other hand, since the interval data_window of two complemented signals DT/DTB shown in FIG. 4 is much longer, the corresponding data contained in the output signal DT/DTB is able to be fetched easily and correctly by a control circuit without an additional hardwired control. In summary, the invention is not only compatible to the pipelining transmission characteristic of DRAM circuits, but also accelerates the data transfer rate of data paths, thus suitable for high-speed circuit applications.

While certain exemplary embodiments have been described and shown in the accompanying drawings, it is to be understood that such embodiments are merely illustrative of and not restrictive on the broad invention, and that this invention should not be limited to the specific construction and arrangement shown and described, since various other modifications may occur to those ordinarily skilled in the art.

What is claimed is:

1. A sense amplifier-based latch, comprising:
a sense amplifier responsive to a first control signal and a second control signal for amplifying both an input signal and a complementary input signal to generate an amplified signal and a complementary amplified signal; and
a latch circuit for latching voltage levels of both the amplified signal and the complementary amplified signal and generating an output signal and a complementary output signal.

2. The sense amplifier-based latch according to claim 1, further comprising:
an input circuit having a plurality of identical input units, wherein each input unit responsive to a data isolation signal receives a master data line signal and a complementary master data line signal, and wherein there is one single data isolation signal corresponding to one of the plurality of input units is enabled in each period of time such that both the master data line signal and the complementary master data line signal received by the enabled input unit are then outputted as the input signal and the complementary input signal.

3. The sense amplifier-based latch according to claim 1, further comprising:
an output circuit responsive to a third control signal for receiving both the output signal and the complementary output signal and sending the voltage level of the output signal to an I/O data bus.

4. The sense amplifier-based latch according to claim 1, wherein the latch circuit is a latch.

5. The sense amplifier-based latch according to claim 4, wherein the latch comprises a first NAND gate and a second NAND gate, wherein the first NAND gate receives the complementary amplified signal and the complementary output signal to generate the output signal, and wherein the second NAND gate receives the amplified signal and the output signal to generate the complementary output signal.

6. The sense amplifier-based latch according to claim 4, wherein the latch comprises a first NOR gate and a second NOR gate, wherein the first NOR gate receives the complementary amplified signal and the complementary output signal to generate the output signal, and wherein the second NOR gate receives the amplified signal and the output signal to generate the complementary output signal.

7. The sense amplifier-based latch according to claim 1, which is applied to a random access memory circuit.

8. The sense amplifier-based latch according to claim 1, wherein the sense amplifier comprises:
a pre-charge circuit responsive to the first control signal for pre-charging the amplified signal and the complementary amplified signal to a pre-defined voltage level before receiving the input signal and the complementary input signal; and
an amplifier circuit responsive to the first control signal and the second control signal for amplifying voltage levels of both the input signal and the complementary input signal and generating the amplified signal and the complementary amplified signal.
